(19) United States
(12) Patent Application Publication
(10) Pub. No.: US 2020/0389187 A1
(43) Pub. Date: Dec. 10, 2020

(54) METHOD OF TRAINING ARTIFICIAL INTELLIGENCE TO EXECUTE DECODING PROGRAM OF LOW DENSITY PARITY CHECK CODE

(71) Applicant: STORART TECHNOLOGY CO., LTD., Hsinchu (TW)

(72) Inventors: HSIANG-EN PENG, HSINCHU (TW); SHENG-HAN WU, HSINCHU (TW)

(21) Appl. No.: 16/434,975

(22) Filed: Jun. 7, 2019

(51) Int. Cl. H03M 13/11; G06N 20/00; G06N 3/04

(52) U.S. Cl. CPC H03M 13/1125; H03M 13/1134; H03M 13/1148; G06N 3/04; G06N 20/00

(57) ABSTRACT

A method of training artificial intelligence to execute a decoding program of a low density parity check code, which includes steps of: providing check nodes and variable nodes; outputting accessed bit values stored in memory units to the variable nodes; providing initial log-likelihood ratios to the variable nodes; decoding the accessed bit values based on the initial log-likelihood ratios to output decoded bit values at the variable nodes; executing checking programs at the check nodes to determine whether or not the decoded bit values are equal to data bit values to be stored in the memory units, if yes, outputting a correct message, if not, outputting an error message and then executing the next step; initiating an artificial intelligence neural network system to use machine learning to analyze practical log-likelihood ratios; and decoding the accessed bit values based on the practical log-likelihood ratios at the variable nodes.

### FIELD OF THE DISCLOSURE

The present disclosure relates to a decoding method, and more particularly to a method of training artificial intelligence to execute a decoding program of a low density parity check code.

### BACKGROUND OF THE DISCLOSURE

Memories are seeing widespread use in recent years. However, memories may be damaged by multiple times of erasing and writing data, resulting in an increased probability of error and a significantly reduced reliability of the non-volatile memory. Therefore, it is necessary to improve the reliability of the non-volatile memory by design techniques such as error correction techniques, such that a lifetime of a product can be prolonged and an operation state of the product can be more stable.

An error correction module for correcting error data read by the non-volatile memory is disposed in a control circuit of the memory to eliminate errors caused by external factors in the non-volatile memory, thereby prolonging the lifetime of the non-volatile memory. A common error correction coding technology, such as a Bose-Chaudhuri-Hocquenghem (BCH) coding technology, is capable of fast computation and has a correction capability that increases with the increase of the number of redundant bits. However, the BCH coding technology cannot keep up with the rapid improvement of manufacturing technologies of the non-volatile memory, and cannot provide a sufficient correction capability. Therefore, a Low Density Parity Code (LDPC) error correction technology widely used in the field of communication and having a strong correction capability is now also being used in data storage.

### SUMMARY OF THE DISCLOSURE

In response to the above-referenced technical inadequacies, the present disclosure provides a method of training artificial intelligence to execute a decoding program of a low density parity check code for a storage device including a plurality of memory units each storing one or more accessed bit values. The method includes the following steps: (a) providing a plurality of check nodes and a plurality of variable nodes; (b) connecting each check node to the one or more variable nodes; (c) outputting the accessed bit values stored in the one or more memory units of the storage device respectively to the variable nodes; (d) providing a plurality of initial log-likelihood ratios respectively to the variable nodes; (e) decoding the accessed bit value at each variable node to output a decoded bit value to the check node corresponding the variable node by executing an initial decoding program based on the initial log-likelihood ratio; (f) executing a checking program for determining whether or not each decoded bit value is equal to a data bit value to be stored in the memory unit at each check node, in response to determining the decoded bit value to be equal to the data bit value to be stored in the memory unit, outputting an correct message, in response to determining the decoded bit value to be not equal to the data bit value to be stored in the memory unit, outputting an error message and then performing step (g); (g) initiating an artificial intelligence neural network system to use machine learning to analyze each error message and a reference log-likelihood ratio received from an external system to output a practical log-likelihood ratio; and (h) decoding the accessed bit value indicated by the error message received at each variable node by executing a practical decoding program based on the practical log-likelihood ratio relative to the initial log-likelihood ratio to output the decoded bit value, and then performing step (f).

As described above, the present disclosure provides the method of training artificial intelligence to execute the decoding program of the low density parity check code for the storage device, which uses the low density parity check code in each iterative program. The artificial intelligence neural network system uses machine learning to analyze the practical log-likelihood ratios and determine the order of decoding the accessed bit values, according to the message indicating that the accessed bit values fail to be decoded, the initial log-likelihood ratios based on which the accessed bit values fail to be decoded, and the reference log-likelihood ratios from the external system. The accessed bit values are sequentially decoded to obtain the correct decoded bit values based on the practical log-likelihood ratios at the variable nodes. Therefore, the method of the present disclosure achieves a better convergence effect and reduces a time required for each iterative program.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a flowchart diagram of a method of training artificial intelligence to execute a decoding program of a low density parity check code according to a first embodiment of the present disclosure.

FIG. 2 is a Tanner diagram of a decoding process of the method of training artificial intelligence to execute the decoding program of the low density parity check code according to the first embodiment of the present disclosure.

FIG. 3 is a Tanner diagram of training an artificial intelligence neural network system to execute the decoding program in the method of training artificial intelligence to execute the decoding program of the low density parity check code according to the first embodiment of the present disclosure.

FIG. 4 is a flowchart diagram of a method of training artificial intelligence to execute a decoding program of a low density parity check code according to a second embodiment of the present disclosure.

FIG. 5 is a Tanner diagram of training an artificial intelligence neural network system to execute the decoding program in the method of training artificial intelligence to execute the decoding program of the low density parity check code according to the second embodiment of the present disclosure.

FIG. 6 is a flowchart diagram of a method of training artificial intelligence to execute a decoding program of a low density parity check code according to a third embodiment of the present disclosure.

FIG. 7 is a Tanner diagram of training an artificial intelligence neural network system to determine a decoding order in the method of training artificial intelligence to execute the decoding program of the low density parity check code according to the third embodiment of the present disclosure.

FIG. 8 is a flowchart diagram of a method of training artificial intelligence to execute a decoding program of a low density parity check code according to a fourth embodiment of the present disclosure.

FIG. 9 is a schematic diagram of a parity check matrix applied by the method of training artificial intelligence to execute the decoding program of the low density parity check code according to the fourth embodiment of the present disclosure.

FIG. 10 is a Tanner diagram of determining a decoding order in the method of training artificial intelligence to execute the decoding program of the low density parity check code according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

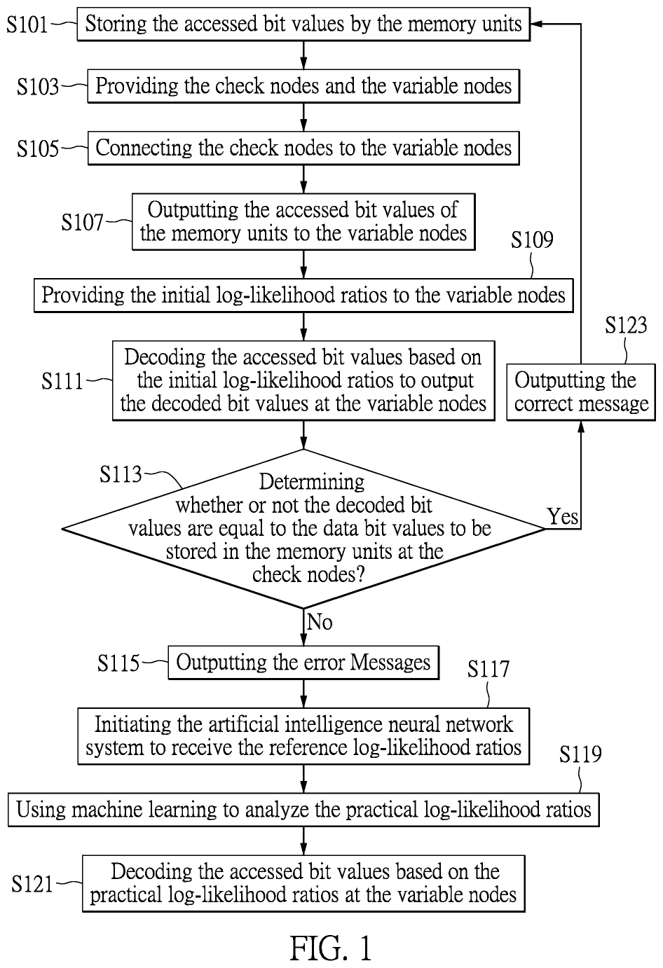

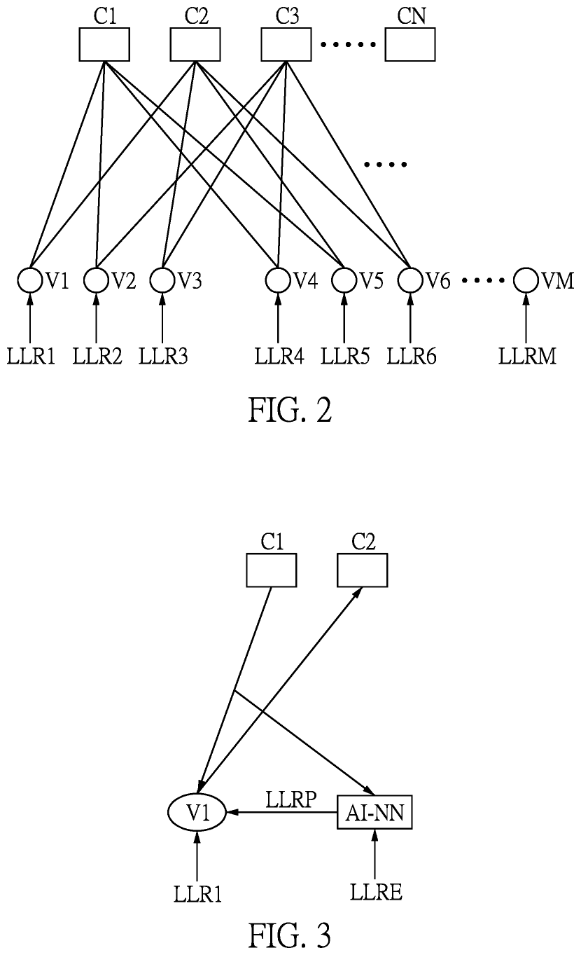

Reference is made to FIGS. 1, 2 and 3, wherein FIG. 1 is a flowchart diagram of a method of training artificial intelligence to execute a decoding program of a low density parity check code according to a first embodiment of the present disclosure, FIG. 2 is a Tanner diagram of a decoding process of the method of training artificial intelligence to execute the decoding program of the low density parity check code according to the first embodiment of the present disclosure, FIG. 3 is a Tanner diagram of training an artificial intelligence neural network system to execute the decoding program in the method of training artificial intelligence to execute the decoding program of the low density parity check code according to the first embodiment of the present disclosure.

As shown in FIG. 1, in the embodiment, the method of training artificial intelligence to execute the decoding program of the low density parity check code includes the following steps S101 to S123. Steps S101 to S113 shown in FIG. 1 correspond to the decoding process shown in the Tanner diagram of FIG. 2. Steps S115 to S123 shown in FIG. 1 correspond to a failure decoding process shown in the Tanner diagram of FIG. 3.

In the embodiment, the method of training artificial intelligence to execute the decoding program of the low density parity check code is applicable for various storage devices such as a solid state drive, etc. The storage device includes a plurality of memory units such as memory cells each storing one or more accessed bit values. For example, the memory unit may be classified into a single-level cell (SLC), a multi-level cell (MLC) or a quad-level cell (QLC) and so on, depending on the bit amount of data to be stored therein. In detail, the single-level cell can store only one bit of data. The multi-level cell can store not more than two bits of data. The quad-level cell can store not more four bits of data.

In step S101, the one or more bit values are stored in the one or more memory units of the storage device. For convenience of illustration, as used herein, the bit value to be stored in the memory unit is represented by a data bit value, the bit value that has been stored in the memory unit is represented by an accessed bit value, and the bit value generated by decoding the accessed bit value is represented by a decoded bit value.

In step S103, the check nodes and the variable nodes are provided. The number of the variable nodes may depend on the number of the check nodes. For example, as shown in FIG. 2, an N number of check nodes and an M number of variable nodes are provided, wherein M has a larger value than N, but the present disclosure is not limited thereto. In practice, three or less check nodes and six or less variable nodes may be provided.

In step S105, the check node is connected to the one or more variable nodes. For example, as shown in FIG. 2, a check node C1 is connected to variable nodes V1, V2, V4, V5, a check node C2 is connected to variable nodes V1, V3, V5, V6, and a check node C3 is connected to the variable nodes V2, V3, V4, V6. Any bit value and instruction may be transmitted between the check nodes and the variable nodes.

In other words, the different variable nodes may be connected to the same check node. For example, as shown in FIG. 2, the variable nodes V1, V3, V5, V6 may be connected to the same check node C2 and the variable nodes V2, V3, V6, V6 may be connected to the same check node C3.

In step S107, the accessed bit values stored in the memory units of the storage device are outputted to the variable nodes. The same or different accessed bit values, each being logic 0 or logic 1, may be received respectively at the variable nodes. In detail, the accessed bit values that are independent from each other or included in the same digital bit stream may be outputted from the memory units of the storage device and received sequentially or simultaneously at the variable nodes.

For example, if a bit stream of “001011” including six logic bit values is stored in the same memory unit, one bit value of logic 0 is received at the variable node V1, another bit value of logic 0 is received at the variable node V2, one bit value of logic 1 is received at the variable node V3, yet another bit value of logic 0 is received at the variable node V4, another bit value of logic 1 is received at the variable node V5, and yet another bit value of logic 1 is received at the variable node V6. Alternatively, the bit values of logic 1, 1, 0, 1, 0 and 0 are received respectively at the variable nodes V1 to V6. In practice, each bit value may be received at any variable node, and is not limited to being received at a specific variable node depending on an order that the bit values are arranged in the bit stream.

Alternatively, the accessed bit values stored in the same or different memory units may be received randomly at the variable nodes V1 to V6. Alternatively, if the memory units are arranged in a storage array of the storage device, the accessed bit values of the memory units may be received at the variable nodes V1 to V6, depending on column/row positions of the memory units arranged in the storage array. It should be understood that the configurations and the transmission paths of the bit values between the memory units and the variable nodes are merely illustrative in the embodiment, and the present disclosure is not limited thereto.

In step S109, initial log-likelihood ratios are provided to the variable nodes. For example, one initial log-likelihood ratio or one initial log-likelihood ratio group including a plurality of initial log-likelihood ratios is received at each variable node. As shown in FIG. 2, the same or different initial log-likelihood ratios LLR1 to LLRM are received respectively at variable nodes LLR1 to LLRM.

In step S111, each accessed bit value is decoded by executing an initial decoding program based on the initial log-likelihood ratio at the variable node to output the decoded bit value to the check node corresponding to the variable node. The initial decoding programs may be sequentially or simultaneously executed at the variable nodes.

If the different initial log-likelihood ratios are received respectively at the variable nodes, the different initial decoding programs are executed respectively at the variable nodes. Under this condition, even if the same accessed bit value is decoded respectively at the variable nodes, different decoded bit values may be outputted. The initial decoding programs may be executed by one or more decoder or other electronic components having decoding capabilities.

Further, after the accessed bit value stored in the memory unit of the storage device is decoded by executing the initial decoding program based on the initial log-likelihood ratio, the decoded bit value that is or is not equal to the accessed bit value is received at the check node.

In step S113, a checking program is executed for determining whether or not the decoded bit value generated by executing the initial decoding program is equal to the data bit value to be stored in the memory unit at the check node.

In detail, the memory unit of the storage device may wrongly identify the data bit value when accessing the data bit value. For example, the data bit value of logic 0 may be wrongly identified as the data bit value of logic 1 and the wrong data bit value of logic 1 is stored in the memory unit. Alternatively, the data bit value of logic 1 may be wrongly identified as the data bit value of logic 0 and the wrong data bit value of logic 0 is stored in the memory unit. Alternatively, the data bit value of logic 1 or 0 may be identified as invalid data and the invalid data is stored in the memory unit.

If the decoded bit value generated by executing the initial decoding program is determined to be equal to the data bit value to be stored in the memory unit at the check node, step S123 is then performed. Conversely, if the decoded bit value generated by executing the initial decoding program is determined to be not equal to the data bit value to be stored in the memory unit at the check node, step S115 is then performed.

In step S115, an error message is outputted to an artificial intelligence neural network system (AI-NN) and the variable node from the corresponding check node, and step S117 is then performed. As shown in FIG. 3, the error message is outputted to the artificial intelligence neural network system AI-NN and the variable node V1 from the check node C1.

In step S117, if the error message outputted from the check node indicates that the memory unit of the storage device stores the wrong bit value, the artificial intelligence neural network system is initiated to receive one or more reference log-likelihood ratios from an external system such an external look-up table.

In step S119, the artificial intelligence neural network system uses machine learning to analyze the error message and the reference log-likelihood ratios to output practical log-likelihood ratios that are different from the initial log-likelihood ratios.

As shown in FIG. 3, when the error message is outputted to the artificial intelligence neural network system AI-NN and the variable node V1 from the check node C1, the artificial intelligence neural network system AI-NN is initiated. Then, the artificial intelligence neural network system AI-NN uses machine learning to analyze the wrong decoded bit value such as logic 0 that is generated at the variable node V1 and indicated by the error message, the data bit value such as logic 1 to be stored, and the log-likelihood ratio LLR1 based on which the accessed bit value may not be decoded to obtain the correct decoded bit value such as logic 1 that is equal to the data bit value such as logic 1. In addition, the artificial intelligence neural network system AI-NN may obtain the reference log-likelihood ratio LLRE according to the above analysis result. The artificial intelligence neural network system AI-NN may then output the practical log-likelihood ratio LLRP that is different from the initial log-likelihood ratio LLR1 to the variable node V1 according to the reference log-likelihood ratio LLRE. The practical log-likelihood ratio may be or not be equal to the reference log-likelihood ratio.

In step S121, when the error message received at the variable node from the check node, the accessed bit value indicated by the error message is decoded by executing the practical decoding program based on the practical log-likelihood ratio relative to the initial log-likelihood ratio. The accessed bit value is decoded to obtain the decoded bit value that is equal to the data bit value by executing the decoding program based on the practical log-likelihood ratio analyzed by the artificial intelligence neural network system at the variable node.

In step S123, when the accessed bit value is decoded to obtain the decoded bit value that is equal to the data bit value to be stored in the memory unit by executing the decoding program based on the initial or practical log-likelihood ratio at the variable node, an correct message is outputted to the storage device from the check node. When the storage device receives the correct message indicating that the memory unit stores the correct data bit value, that is, the accessed bit value and the decoded bit value are both equal to the data bit value, a storage controller of the storage device may instruct the memory unit to further access new data bit values.

As shown in FIG. 3, when the accessed bit value is successfully decoded by executing the practical decoding program based on the practical log-likelihood ratio LLRP relative to the initial log-likelihood ratio LLR1 to generate the decoded bit value that is equal to the data bit value to be stored at the variable node V1, the correct message is outputted to the check node C2 from the variable node V1. Then, another accessed bit value stored in a memory unit of the storage device that is the same as or different from the above memory unit in which the above accessed bit value is stored may be received at the same variable node V1 or a different variable node in practice, and decoded to generate another decoded bit value by executing the initial log-likelihood ratio LLR1 or the practical log-likelihood ratio. Then, the another decoded bit value generated at the same variable node V1 or a different variable node in practice is checked at the check node C2.

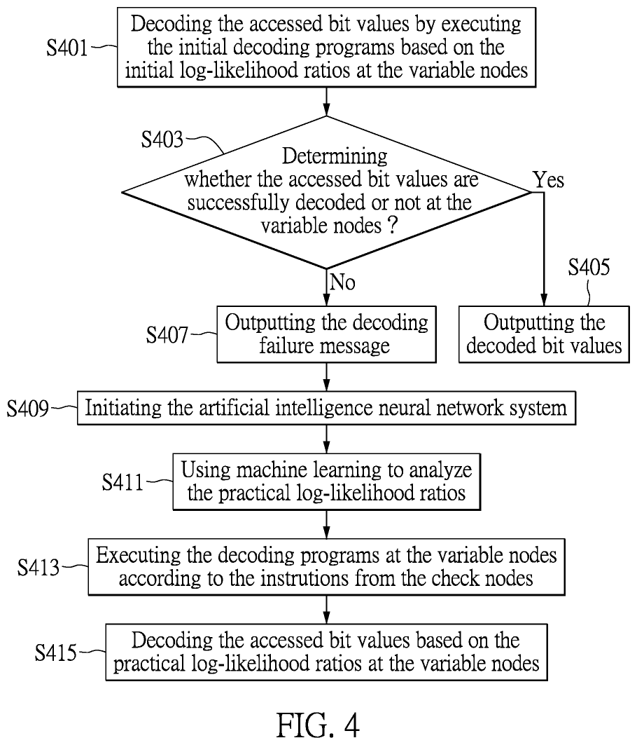

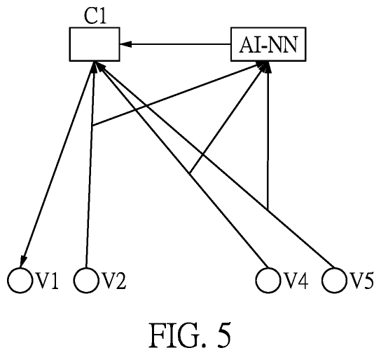

Reference is made to FIGS. 4 and 5, wherein FIG. 4 is a flowchart diagram of a method of training artificial intelligence to execute a decoding program of a low density parity check code according to a second embodiment of the present disclosure, FIG. 5 is a Tanner diagram of training an artificial intelligence neural network system to execute the decoding program in the method of training artificial intelligence to execute the decoding program of the low density parity check code according to the second embodiment of the present disclosure. As shown in FIG. 4, in the embodiment, the method of training artificial intelligence to execute the decoding program of the low density parity check code includes the following steps S401 to S415 for the storage device. The storage device includes the plurality of memory units each storing the one or more accessed bit values.

In step S401, the accessed bit value is decoded by executing the initial decoding program based on the initial log-likelihood ratio at the variable node. For example, as shown in FIG. 5, the one or more variable nodes such the five variable nodes V1 to V5 and the one or more variable nodes such the check node C1 are provided. The check node C1 is connected to the variable nodes V1 to V5.

When the initial log-likelihood ratio and the accessed bit value such as logic 0 or logic 1 of the memory unit of the storage device are received at the variable node V2, the accessed bit value is decoded by executing the initial decoding program based on the initial log-likelihood ratio to obtain the decoded bit value such as logic 0 or logic 1 at the variable node V2.

In step S403, it is determined whether or not the accessed bit value stored in the memory unit is decoded successfully at the variable node. If the accessed bit value stored in the memory unit is successfully decoded at the variable node, a valid decoded bit value such as logic 0 or logic 1 is generated, and step S405 is then performed. Conversely, if the accessed bit value stored in the memory unit fails to be decoded at the variable node, an invalid decoded bit value is generated, or any decoded bit value is not generated, step S407 is then performed.

In step S405, the decoded bit value is outputted to the check node from the corresponding variable node. In the embodiment, as shown in FIG. 5, the decoded bit values are outputted to the check node C1 and the artificial intelligence neural network system respectively from the variable nodes V2 to V5.

In step S407, the decoding failure message is outputted to the check node and the artificial intelligence neural network system from the variable node.

For example, as shown in FIG. 5, the accessed bit values stored in the memory unit are sequentially decoded at the variable nodes V2 to V5. If the accessed bit value fails to be decoded at the variable node V1, any bit value or message may not be outputted to the check node C1 from the variable node V1. However, when the decoded bit values are sequentially or simultaneously outputted to the check node C1 from the other variable nodes V2 to V5, a decoding result inquiry message may be optionally outputted to the variable node V1 from the check node C1 to request the variable node V1 to respond with a decoding result to the check node C1. In this way, the decoding program can be determined at the check node C1 to be successfully performed at the variable node V1, or it may be determined that no decoding program is performed. Alternatively, when the accessed bit value fails to be decoded at the variable node V1, the decoding failure message is actively outputted to the check node C1.

In step S409, the artificial intelligence neural network system is initiated by the decoding failure message from the variable node. As shown in FIG. 5, when the decoding failure message is outputted to the artificial intelligence neural network system AI-NN from the one or more variable nodes V2 to V5, the artificial intelligence neural network system AI-NN is initiated.

In step S411, the artificial intelligence neural network system uses machine learning to analyze the decoding failure message to output the practical log-likelihood ratio. As shown in FIG. 5, the artificial intelligence neural network system AI-NN uses machine learning to analyze the decoding failure message to output the practical log-likelihood ratio to the check node C1. The decoding failure message includes a message indicating the variable node at which the decoding program is executed, a message indicating the memory unit of the storage device in which the accessed bit value is to be decoded, a message indicating that the accessed bit value is logic 0 or logic 1, a message indicating that the accessed bit value fails to be decoded, a message indicating the initial log-likelihood ratio based on which the accessed bit value fails to be decoded, and the like.

In step S413, the practical log-likelihood ratio corresponding to the decoding failure message is obtained at the check node. A re-decoding indication message is outputted from the check node to the variable node, according to the practical log-likelihood ratio and the decoding failure message.

In step S415, the accessed bit value is decoded by executing the practical decoding program based on the practical log-likelihood ratio at the variable node, according to the re-decoding indication message from the check node.

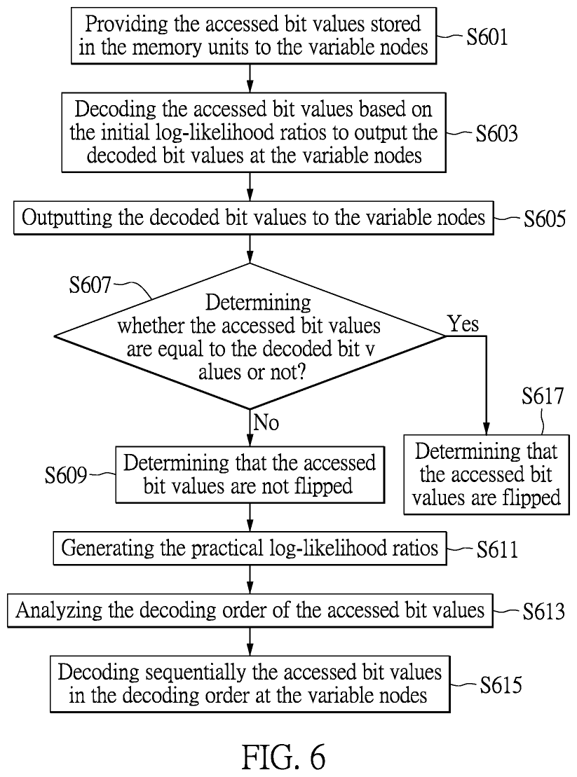

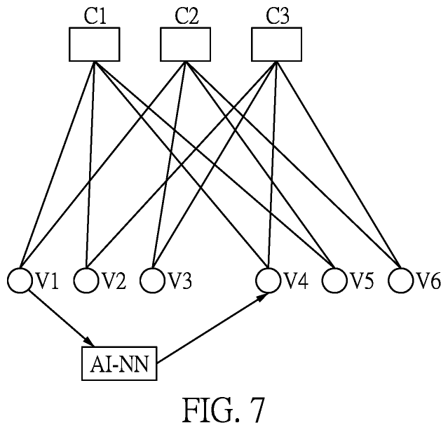

Reference is made to FIGS. 6 and 7, wherein FIG. 6 is a flowchart diagram of a method of training artificial intelligence to execute a decoding program of a low density parity check code according to a third embodiment of the present disclosure, FIG. 7 is a Tanner diagram of training an artificial intelligence neural network system to determine a decoding order in the method of training artificial intelligence to execute the decoding program of the low density parity check code according to the third embodiment of the present disclosure. As shown in FIG. 6, in the embodiment, the method of training artificial intelligence to execute the decoding program of the low density parity check code includes the following steps S601 to S617 for the storage device. The storage device includes the plurality of memory units each storing the one or more accessed bit values.

In step S601, the accessed bit value stored in the memory unit is provided to the variable node.

In step S603, the accessed bit value is decoded by executing the initial decoding program based on the initial log-likelihood ratio or the practical decoding program based on the practical log-likelihood ratio to generate the decoded bit value at the variable node.

In step S605, the decoded bit value is outputted to the check node from the variable node.

In step S607, the artificial intelligence neural network system uses machine learning to determine whether or not the accessed bit value stored in the memory unit is equal to the decoded bit value generated by executing the initial or practical decoding program, based on the initial or the practical log-likelihood ratio, on the accessed bit value at the variable node.

In step S609, if the accessed bit value stored in the memory unit is determined to be equal to the decoded bit value, it is determined that the accessed bit value can be flipped based on the initial log-likelihood ratio or the practical log-likelihood ratio, and then step S617 is performed. More precisely, step S113 is also performed. In step S113, it is determined whether or not the decoded bit value is equal to the data bit value to be stored in the memory unit. In this way, the artificial intelligence neural network system uses machine learning to determine whether or not the wrong accessed bit value stored in the memory unit can be flipped into the correct decoded bit value that is equal to the data bit value by executing the initial decoding program based on the initial log-likelihood ratio or the practical decoding program based on the practical log-likelihood ratio, according to the above determination result and the checking result.

Conversely, if the accessed bit value stored in the memory unit is determined to be not equal to the decoded bit value, it is determined that the wrong accessed bit value is not flipped into the correct decoded bit value that is equal to the data bit value by executing the initial decoding program based on the initial log-likelihood ratio or the practical decoding program based on the practical log-likelihood ratio. Under this condition, access failure cannot be corrected based on the initial log-likelihood ratio or the practical log-likelihood ratio, and step S611 is then performed.

In step S611, if the accessed bit value fails to be decoded to generate the decoded bit value that is equal to the data bit value by executing the initial decoding program based on the initial log-likelihood ratio, the artificial intelligence neural network system uses machine learning to analyze one practical log-likelihood ratio that is different from the initial log-likelihood ratio, according to the reference log-likelihood ratio and the initial log-likelihood ratio. Further, if the accessed bit value fails to be decoded to generate the decoded bit value that is equal to the data bit value by executing the practical decoding program based on the one practical log-likelihood ratio, the artificial intelligence neural network system uses machine learning to analyze another practical log-likelihood ratio different from the one practical log-likelihood ratio, according to another reference log-likelihood ratio and the one practical log-likelihood ratio.

In step S613, the artificial intelligence neural network system uses machine learning to analyze a decoding order of the accessed bit values that fail to be flipped into the decoded bit values that are equal to the data bit values by executing the initial or practical decoding programs. That is, the decoding order of the accessed bit values indicated by all the error messages at step S115 is analyzed.

In step S615, the accessed bit values that are not flipped by executing the practical decoding program and indicated by all the error messages are sequentially decoded in the decoding order at the variable nodes. For example, as shown in FIG. 7, the artificial intelligence neural network system AI-NN uses machine learning to determine that the decoding program is to be executed at the variable node V4 after the decoding program is executed at the variable node V1.

In step S617, if the accessed bit value is decoded to generate the decoded bit value that is not equal to the accessed bit value and equal to the equal to the data bit value by executing the practical decoding program based on the one or another practical log-likelihood ratio, the accessed bit value is determined be successfully flipped into the correct decoded bit value.

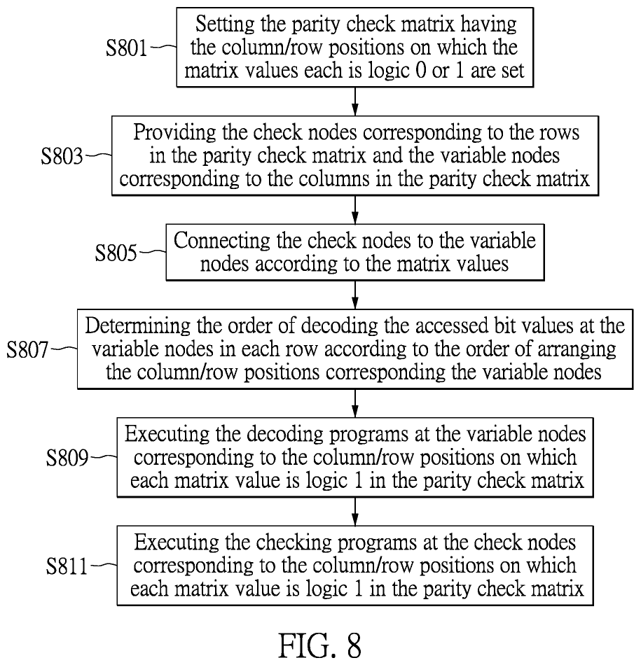

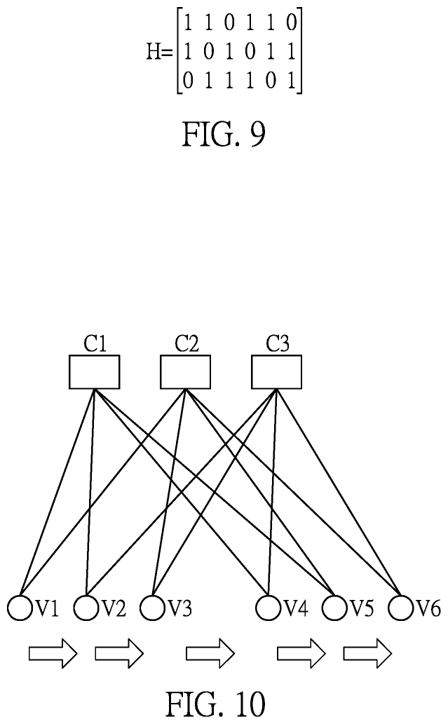

Reference is made to FIGS. 8, 9 and 10, wherein FIG. 8 is a flowchart diagram of a method of training artificial intelligence to execute a decoding program of a low density parity check code according to a fourth embodiment of the present disclosure, FIG. 9 is a schematic diagram of a parity check matrix applied by the method of training artificial intelligence to execute the decoding program of the low density parity check code according to the fourth embodiment of the present disclosure, and FIG. 10 is a Tanner diagram of determining a decoding order in the method of training artificial intelligence to execute the decoding program of the low density parity check code according to the fourth embodiment of the present disclosure.

As shown in FIG. 8, in the embodiment, the method of training artificial intelligence to execute the decoding program of the low density parity check code includes the following steps S801 to S811 for the storage device. The storage device includes the plurality of memory units each storing the one or more accessed bit values.

In step S801, the parity check matrix having a plurality of column/row positions on which matrix values are set is provided. For example, as shown in FIG. 9, the parity check matrix has 3 rows and 6 columns. Eighteen matrix values each being logic 0 or logic 1 are in the eighteen column/row positions of the parity check matrix. It should be understood that the number of the rows and the columns and the matrix values of the parity check matrix are merely illustrative in the embodiment, and the present disclosure is not limited thereto. In practice, different parity check matrices may be set according to actual requirements.

In step S803, the check nodes corresponding to the rows of the parity check matrix and the variable nodes corresponding to the columns of the parity check matrix are provided. The connections between and the numbers of the check nodes and the variable nodes depend on the parity check matrix. For example, as shown in FIG. 9, a parity check matrix H has three rows. As shown in FIG. 10, the three check nodes C1 to C3 are provided in correspondence to the three rows of the parity check matrix H. As shown in FIG. 9, the parity check matrix H has six columns. As shown in FIG. 10, the six variable nodes V1 to V6 are provided in correspondence to the six columns of the parity check matrix H.

In step S805, the check nodes are connected to the corresponding variable nodes according to the matrix values of the parity check matrix. For example, as shown in FIG. 9, the parity check matrix H has the matrix value of logic 1 in first, second, fourth and fifth columns, first row. Accordingly, as shown in FIG. 10, the first check node C1 corresponding to the first row is connected to the variable nodes V1, V2, V4, V5 corresponding to the first, second, fourth and fifth columns. The parity check matrix H has the matrix value of logic 0 in third and sixth columns. Accordingly, the first check node C1 is not connected to the variable nodes V3 and V6.

In addition, as shown in FIG. 9, the parity check matrix H has the matrix value of logic 1 in first, third, fifth and sixth columns. Accordingly, as shown in FIG. 10, the second check node C2 corresponding to the second row is connected to the variable nodes V1, V3, V5, V6 corresponding to the first, second, third, fifth and sixth columns. The parity check matrix H has the matrix value of logic 0 in second and fourth columns. Accordingly, the second check node C2 is not connected to the variable nodes V2 and V4.

In addition, as shown in FIG. 9, the parity check matrix H has the matrix value of logic 1 in second, third, fourth and sixth columns. Accordingly, as shown in FIG. 10, the third check node C3 corresponding to the third row is connected to the variable nodes V2, V3, V4, V6 corresponding to the first, second, third, fourth and sixth columns. The parity check matrix H has the matrix value of logic 0 in first and fifth columns. Accordingly, the third check node C3 is not connected to the variable nodes V1 and V5.

In step S807, a decoding order of decoding the accessed bit values in each column in the parity check matrix at the variable nodes is determined according to an arranged order of column positions of the column/row positions in the parity check matrix. As shown in FIG. 8, the variable nodes V1 to V6 respectively correspond to the first to sixth columns of the parity check matrix H. Accordingly, the decoding programs are executed sequentially at the variable nodes V1 to V6. Further, an order of checking the decoded bit values generated at the variable nodes may depend on the decoding order at the check nodes.

In step S809, the accessed bit values stored in the memory units of the storage device are sequentially decoded by executing initial or practical decoding programs at the variable nodes corresponding to the column/row positions on which each matrix value is logic 1 in the parity check matrix.

In step S811, the checking programs are executed at the check nodes respectively for checking the decoded bit values generated at the variable nodes corresponding to the column/row positions on which each matrix value is logic 1 in the parity check matrix.

In summary, the present disclosure provides the method of training artificial intelligence to execute the decoding program of the low density parity check code for the storage device, which uses the low density parity check code in each iterative program. The artificial intelligence neural network system uses machine learning to analyze the practical log-likelihood ratios and determine the order of decoding the accessed bit values, according to the message indicating that the accessed bit values fail to be decoded, the initial log-likelihood ratios based on which the accessed bit values fail to be decoded, and the reference log-likelihood ratios from the external system. The accessed bit values are sequentially decoded to obtain the correct decoded bit values based on the practical log-likelihood ratios at the variable nodes. Therefore, the method of the present disclosure achieves a better convergence effect and reduces a time required for each iterative program.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method of training artificial intelligence to execute a decoding program of a low density parity check code for a storage device including a plurality of memory units each storing one or more accessed bit values, comprising the following steps:
(a) providing a plurality of check nodes and a plurality of variable nodes;
(b) connecting each check node to one or more of the variable nodes;
(c) outputting the accessed bit values stored in one or more of the memory units of the storage device respectively to the variable nodes;
(d) providing a plurality of initial log-likelihood ratios respectively to the variable nodes;
(e) decoding the accessed bit value at each variable node to output a decoded bit value to the check node corresponding the variable node by executing an initial decoding program based on the initial log-likelihood ratio;
(f) executing a checking program for determining whether or not each decoded bit value is equal to a data bit value to be stored in the memory unit at each check node, in response to determining the decoded bit value to be equal to the data bit value to be stored in the memory unit, outputting an correct message, in response to determining the decoded bit value to be not equal to the data bit value to be stored in the memory unit, outputting an error message and performing step (g);
(g) initiating an artificial intelligence neural network system to use machine learning to analyze each error message and a reference log-likelihood ratio received from an external system to output a practical log-likelihood ratio; and
(h) decoding the accessed bit value indicated by the error message received at each variable node by executing a practical decoding program based on the practical log-likelihood ratio relative to the initial log-likelihood ratio to output the decoded bit value, and then performing step (f).

2. The method of claim 1, further comprising the following steps:
(i) determining whether or not each decoded bit value is equal to the data bit value to be stored in the memory unit at each check node, in response to determining each decoded bit value to be equal to the data bit value to be stored in the memory unit, outputting the correct message to the variable node, in response to determining each decoded bit value to be not equal to the data bit value to be stored in the memory unit, outputting the error message to the variable node and the artificial intelligence neural network system and performing step (j); and
(j) initiating the artificial intelligence neural network system to use machine learning to analyze the error message received from the check node to output the practical log-likelihood ratio to the variable node.

3. The method of claim 1, further comprising the following steps:
(k) decoding each accessed bit value by executing an initial decoding program based on the initial log-likelihood ratio at the variable node;
(l) determining whether or not each accessed bit value stored in the memory unit is successfully decoded based on the initial log-likelihood ratio at the variable node, in response to determining the accessed bit value to be successfully decoded, outputting the decoded bit value to the corresponding variable node, in response to determining the accessed bit value to be not successfully decoded, outputting a decoding failure message to the variable node and the intelligence neural network system;
(m) initiating the artificial intelligence neural network system to use machine learning to analyze each decoding failure message and the reference log-likelihood ratio to output the corresponding practical log-likelihood ratio to the check node;
(n) outputting a re-decoding indication message according to the practical log-likelihood ratio and the decoding failure message to the variable node from the check node; and
(o) decoding each accessed bit value by executing the practical decoding program based on the practical log-likelihood ratio at the variable node, according to the re-decoding indication message from the check node.

4. The method of claim 1, further comprising the following steps:
(p) providing the accessed bit values stored in the memory units respectively to the check nodes;
(q) outputting the decoded bit values generated by executing the initial decoding program based on the initial log-likelihood ratio respectively to the variable nodes from the variable nodes;
(r) initiating the artificial intelligence neural network system to use machine learning to determine whether or not each accessed bit value is equal to the decoded bit value, in response to determining each accessed bit value to be not equal to the decoded bit value, determining that the accessed bit value is flipped by executing the initial decoding program, in response to determining each accessed bit value to be equal to the decoded bit value, determining that the accessed bit value is not flipped by executing the initial decoding program;
(s) initiating the artificial intelligence neural network system to use machine learning to analyze the practical log-likelihood ratio according to the reference log-likelihood ratio and the initial log-likelihood ratio;
(t) initiating the artificial intelligence neural network system to use machine learning to analyze a decoding order of the accessed bit values that are not flipped by executing the initial decoding programs and indicated by all the error messages; and
(u) decoding sequentially the accessed bit values that are not flipped by executing the initial decoding programs and indicated by all the error messages in the decoding order at the variable nodes.

5. The method of claim 1, further comprising the following steps:
(v) providing the accessed bit values stored in the memory units respectively to the check nodes;
(w) outputting the decoded bit values generated by executing the practical decoding programs based on the practical log-likelihood ratios respectively to the check nodes from variable nodes;
(x) initiating the artificial intelligence neural network system to use machine learning to determine whether or not each accessed bit value is equal to the decoded bit value, in response to determining each accessed bit value to be not equal to the decoded bit value, determining that the accessed bit value is flipped by executing the practical decoding program, in response to determining each accessed bit value to be equal to the decoded bit value, determining that the accessed bit value is not flipped by executing the practical decoding program;
(y) initiating the artificial intelligence neural network system to use machine learning to analyze another practical log-likelihood ratio according to another reference log-likelihood ratio and the practical log-likelihood ratio;
(z) initiating the artificial intelligence neural network system to use machine learning to analyze a decoding order of the accessed bit values that are not flipped by executing the practical decoding program and indicated by all the error messages; and
(aa) decoding sequentially the accessed bit values that are not flipped by executing the practical decoding program and indicated by all the error messages in the decoding order at the variable nodes.

6. The method of claim 1, further comprising the following steps:
(bb) setting a parity check matrix having a plurality of column/row positions on which matrix values are set, wherein rows in the parity check matrix respectively correspond to the check nodes, and columns in the parity check matrix respectively correspond to the variable nodes; and
(cc) connecting each check node to the corresponding one or more variable nodes according to the matrix values of the parity check matrix.

7. The method of claim 6, further comprising the following steps:
(dd) setting the matrix value to logic 0 or logic 1 on each column/row position of the parity check matrix;
(ee) executing the initial decoding program or the practical decoding program at the variable nodes corresponding to the column/row positions on which the matrix value is set to logic 1 in the parity check matrix; and
(ff) executing the checking program at the check nodes corresponding to the column/row positions on which the matrix value is set to logic 1 in the parity check matrix.

8. The method of claim 6, further comprising the following step:
(gg) determining an order of decoding the accessed bit values respectively at the variable nodes according to an order that the column/row positions are arranged in the parity check matrix that respectively correspond to the variable nodes.
